(19) United States
(12) Patent Application Publication
(10) Pub. No.: US 2024/0397685 A1
(43) Pub. Date: Nov. 28, 2024

(54) ADJUSTABLE BROADBAND RADAR ABSORBER

(71) Applicants: CONSTRUCTIONS MECANIQUES DE NORMANDIE, Paris (FR); RHEIN TECH LABORATORIES INC, Herndon, VA (US)

(72) Inventors: Thtreswar BEEHARRY, Cherbourg-octeville (FR); Desmond A. FRASER, Herndon, VA (US)

(73) Assignees: CONSTRUCTIONS MECANIQUES DE NORMANDIE, Paris (FR); RHEIN TECH LABORATORIES INC, Herndon, VA (US)

(21) Appl. No.: 18/687,085

(22) PCT Filed: Sep. 28, 2021
(86) PCT No.: PCT/IB2021/000827

§ 371 Date: Feb. 27, 2024

(51) Int. Cl. H05K 9/00

(52) U.S. Cl. CPC H05K 9/0088

(57) ABSTRACT

A radar absorber may be mounted on a surface to be protected. The absorber may include at least a first dielectric layer configured to face away from the surface to be protected, a second dielectric layer configured to face towards the surface to be protected and a water layer enclosed in a volume between the first and the second dielectric layers.

### TECHNICAL FIELD

This disclosure pertains to the field of radar wave absorption. More specifically, the present disclosure relates to a radar absorber intended to be applied to a surface to be protected. The present disclosure also relates to a method of manufacturing and assembling a radar absorber.

### INTRODUCTION

Many vehicular systems, such as military or research aircrafts and vessels, are heavily equipped with antennas and radars dedicated to communication and combat systems. However, the propagation of radar waves from these communication and combat systems causes difficulties regarding their arrangement and positioning. In fact, Electromagnetic Compatibility (EMC) problems may appear such as shadow zones, mismatching of antennas with their generators or strong radar signatures.

To address some EMC problems, it is known to coat a surface with a radar absorber, or Radar Absorbing Material (RAM). In practice, the radar absorber can operate by two mechanisms, namely, the cancellation of the incident wave or its absorption.

The cancellation of the incident wave uses “resonant absorbers”. The absorber is made up of two layers, one of which is partially reflective and the other is fully reflective. The two layers are separated by a distance equivalent to a quarter of the wavelength of the incident wave. By reflection on each of the layers, the radar absorber generates two reflected waves in phase opposition, leading to the cancellation of the incident wave. However, this type of absorber only works for a particular frequency of the incident wave. The effectiveness of the absorber decreases the further away the frequency of the incident wave is from the expected frequency.

Incident wave absorption uses an absorber comprising a reflective layer coated with a dielectric material. The dielectric material is charged with particles that can change the frequency of the incident wave or change its nature. In order to absorb incident waves of different frequencies, it appears possible to provide several layers of dielectric material. However, good performance of this type of radar absorber requires the use of a dielectric material that is not readily available and that can be expensive. The cost, size and weight of the absorber can quickly increase, especially when the absorber comprises multiple layers of dielectric materiel.

There is therefore a need for a radar absorber which does not have the drawbacks of existing absorbers.

### SUMMARY

In one embodiment, a radar absorber may comprise at least:
a first dielectric layer configured to face away from a surface to be protected;
a second dielectric layer configured to face towards from the surface to be protected; and
a frame configured to hold water in a water layer enclosed in a volume between the first and the second dielectric layers.

Such a radar absorber enables absorption of radar waves of various frequencies. Water is a material with high losses over a wide frequency band. The dielectric layers may thus be made of an easily sourced and inexpensive material without compromising the absorption performance of the absorber. Such an absorber, with a good performance to cost ratio, may be used against EMC problems or in order to increase the stealth of a vessel or ship against detection by other radars.

The following features, may be optionally implemented, separately or in combination one with the others:

The radar absorber may further comprise fixing means configured to mount the radar absorber to the surface to be protected, wherein the fixing means may be configured to define a gap between the second dielectric layer and the surface to be protected. The presence of a gap or no gap between the absorber and the surface to be protected is believed to have an impact on the frequency band for which the absorber is particularly responsive. Thus, by adapting the fixing means, modulation of the absorption frequencies intended to be absorbed may be achieved.

In an embodiment, the fixing means may be configured to set a distance separating the surface to be protected from the second dielectric layer, wherein the distance is comprised in an interval between 0 mm and 50 mm, for example. Such a range of distances provides a wide range of frequency bands for which the absorber may be particularly effective.

The fixing means may be adjustable, and may comprise screws. The distance between the absorber and the surface to be protected may therefore be easily adjusted, for example, to change the frequency band for which the absorber is particularly responsive. The same absorber may be suited for a number of applications.

In yet another embodiment, the frame may delimit the volume between the first and the second dielectric layers. The frame may act as a spacer to separate the first and second dielectric layers as desired whilst leaving space for the water layer.

An outer periphery of the frame may be covered with a waterproof material. The waterproof material may contain the water within the volume defined by the frame and prevent undesired leakage during use of the absorber.

The radar absorber may further comprise ribs arranged between the first and the second dielectric layers. The ribs act as spacers to separate the first and second dielectric layers. In addition, frequencies for which the absorber is particularly efficient and exhibits a good performance may be modulated by one or more arrangements of the ribs.

For example, the ribs may form a pattern, and the pattern may comprise one or more geometric shapes. The geometric shapes affect the frequencies for which the absorber is efficient. By forming a pattern with the ribs, the performance of the absorber may be tuned to a particular application.

The pattern may be symmetrical. In such a case, absorption of Transverse Electric (TE) and Transverse Magnetic (TM) propagation modes may be similar for radar wave angles of incidences up to 50°.

In still another embodiment, the pattern may be non-symmetrical. In such a case, as the angle of incidence of the waves increases, the absorption frequency band for the TM mode may shift towards higher frequencies and become larger.

The first and second dielectric layers may be composed of a PolyVinyl Chloride (PVC) or a rubber. These materials have known dielectric properties, while being accessible at low cost. In addition, it appears possible to adapt these materials to follow a curvature of the surface to be protected.

The temperature of the water layer may be held between 5° C. and 45° C. Preferably the water layer may have a temperature of about 25° C. Within the range 5° to 45° C., the properties of the water are particularly suited to absorbing incident radar waves in a desired frequency band.

The first and the second dielectric layers may take the form of continuous plates, of constant thickness and generally planar. Thus, the cost of manufacturing the radar absorber may be reduced, as the dielectric plates may be produced at low cost.

The first dielectric layer may have a thickness of about 4 mm; the second dielectric layer may have a thickness of about 2 mm; and a distance between the first dielectric layer and the second dielectric layer may be about 2 mm. Such dimensions are believed to be particularly suited for good performance of the radar absorber.

In another embodiment, the first dielectric layer may have a thickness of about 2 mm; the second dielectric have layer may a thickness of about 2 mm; and a distance between the first dielectric layer and the second dielectric layer may be about 2 mm. Such a thickness of the first dielectric layer shifts the frequency band for which the radar absorber is particularly efficient towards lower frequencies. The radar absorber may be tuned to minimize absorption in the higher frequency band.

The radar absorber may further comprise at least one intermediate dielectric layer configured between the first dielectric layer and the second dielectric layer, a water layer being configured on either side of each intermediate layer. Thus, by superimposing dielectric layers and water layers, it appears possible to increase the range of frequencies for which the radar absorber is particularly efficient (e.g. low frequency waves, and in particular radio waves within a frequency band of 4-8 Ghz).

In an embodiment, the radar absorber may comprise a resistive layer placed on an outer surface of the first dielectric layer. Thus, it appears possible for the radar absorber to absorb additional frequencies, especially low frequencies such as frequencies in the range 400 MHz to 1 GHz.

In another embodiment, a method for manufacturing a water absorber is provided. Such a method may comprise:
providing at least a first dielectric layer and a second dielectric layer;
configuring a frame between the first dielectric layer and the second dielectric layer, wherein the frame may be configured to hold water and to form a water layer.

Such a method is believed to allow for the ease of manufacture of exemplary radar absorbers that can absorb a wide range of frequencies at a reduced cost.

The following features can be optionally implemented, separately or in combination one with the others in one or more related methods.

The method may further comprise mounting the radar absorber to a surface to be protected, where a distance separating the surface to be protected from the radar absorber may be an interval between 0 mm and 50 mm, for example.

The method may further comprise connecting the frame and the first dielectric layer; and connecting the second dielectric layer and the frame to define a volume between the first and second dielectric layers.

The method may yet further comprise injecting water through an opening of the frame to fill the volume; and applying a waterproof material on an outer periphery of the frame.

In another embodiment, the method may further comprise mounting ribs between the first dielectric layer and the second dielectric layer to separate the first and second dielectric layers. The ribs may be mounted to form a pattern and modulate the frequencies absorbed, the pattern comprising one or more geometric shapes.

The method may further comprise mounting one or more intermediate dielectric layers between the first dielectric layer and the second dielectric layer, each intermediate layer being arranged between two water layers.

### BRIEF DESCRIPTION OF DRAWINGS

Other features, details and advantages will be shown in the following detailed description and on the figures, on which:

FIG. 1 schematically illustrates a cross-sectional view of a radar absorber mounted on a surface to be protected, according to an embodiment.

FIG. 2 schematically illustrates a plan view of a longitudinal cross section of the radar absorber of FIG. 1.

FIGS. 3A to 3E schematically illustrate different embodiments of a radar absorber comprising ribs.

FIG. 4 schematically illustrates fixing means of the radar absorbers of FIG. 1 or 3A to 3E, according to an embodiment

FIG. 5A illustrates reflection versus incident radar wave frequency for the radar absorbers of FIGS. 1 and 3A to 3E, set to absorb a frequency band of 2-3 GHZ.

FIG. 5B illustrates reflection versus incident radar wave frequency for the radar absorbers of FIGS. 1 and 3A to 3E, set to absorb a frequency band of 7-9 GHZ.

FIG. 6A illustrates reflection versus incident radar wave frequency and angle of incidence for the radar absorber of FIG. 3E, set to absorb a frequency band of 2-3 GHZ.

FIG. 6B illustrates reflection versus incident radar wave frequency and angle of incidence for the radar absorber of FIG. 3D, set to absorb a frequency band of 2-3 GHZ.

FIG. 7 schematically illustrates a manufacturing process for the radar absorbers of FIGS. 1 and/or FIGS. 3A to 3E according to an embodiment.

FIG. 8 schematically illustrates a cross sectional view of a radar absorber mounted on a surface to be protected, according to another embodiment.

FIG. 9 schematically illustrates a cross sectional view of a radar absorber mounted on a surface to be protected, according to yet another embodiment.

### DESCRIPTION OF EMBODIMENTS

In the various figures, the same references designate identical or similar elements. As used herein the term “embodiment” or “exemplary” means one example of an inventive radar absorber. These terms may be synonymous with the term “aspect”.

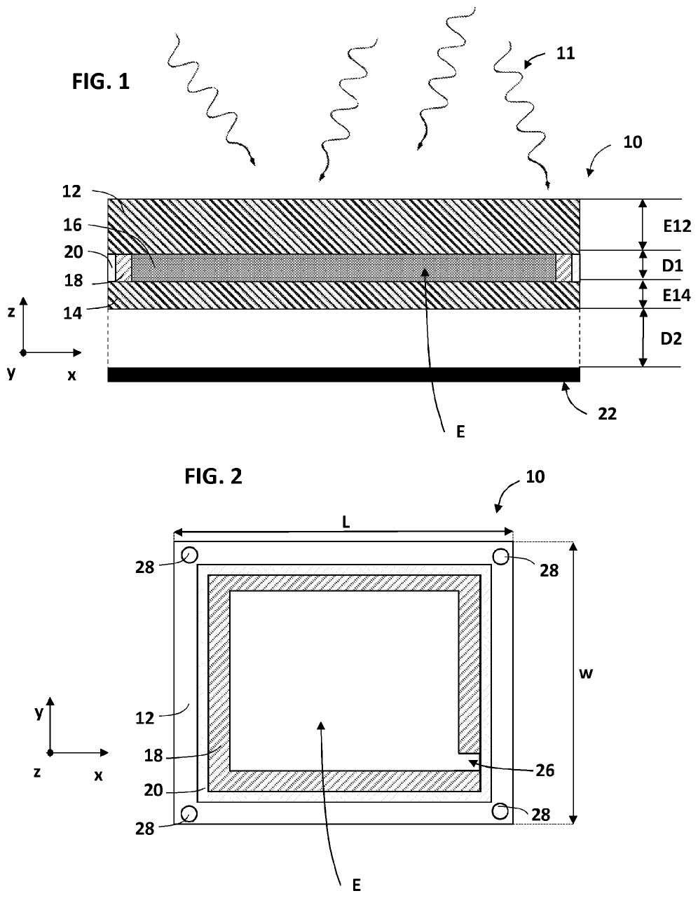

As shown in FIG. 1, an exemplary radar absorber 10 is destined to be mounted on a surface to be protected 22. The radar absorber 10 may comprise a first dielectric layer 12 and a second dielectric layer 14, between which a water layer 16 may be enclosed. The radar absorber 10 may be configured to absorb radar waves 11, characterized by their frequency F and their wavelength A.

The surface to be protected 22 may, for example, be a hull of a ship, a radome wall or a metal duct. Here, the surface to be protected 22 is substantially flat. The radar absorber 10 may be arranged parallel to the surface to be protected 22. In particular, the radar absorber 10 may be arranged such that the first dielectric layer 12 is distant, or faces away, from the layer to be protected 22 and the second layer 14 extends closer to, or faces towards, the surface to be protected 22.

The radar absorber 10 may be mounted to the surface to be protected 22 so as to define a gap between the second dielectric layer 14 and the surface to be protected 22, in the direction perpendicular to the planes of extension of the first and second dielectric 12, 14 (direction z). A distance D2 separating the surface to be protected 22 from the second dielectric layer 14 may be comprised in an interval between 0 mm and 50 mm, for example. This range of distances allows the radar absorber 10 to modulate a range of frequencies for which the radar absorber 10 is believed to be particularly effective. Said another way, the radar absorber 10 may be adapted for different applications, by varying the distance D2 between the absorber 10 and the surface to be protected 22. It should be noted that the gap between the surface to be protected 22 and the second dielectric layer 14 is essentially free space, wherein air can circulate.

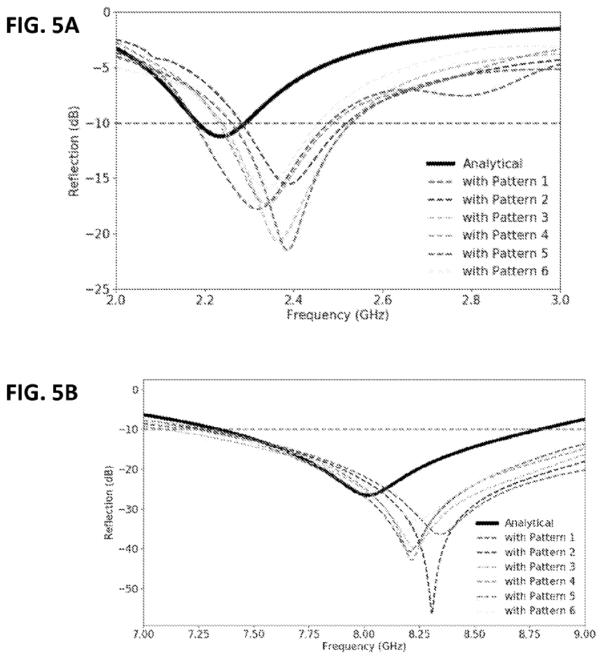

For example, FIGS. 5A and 5B illustrate the absorption of radar waves 11 according to their frequency F. In the figures, the lower the reflection value, the higher the absorption of the radar waves 11 by the radar absorber 10. In FIG. 5A, the distance D2 separating the surface to be protected 22 from the second dielectric layer 14 is 0 mm. An absorption frequency band for which wave absorption is greater than 90% (i.e. below-10 dB reflection) is estimated between around 2.1 and 2.3 GHZ. In comparison, in FIG. 5B, the distance D2 separating the surface to be protected 22 from the second dielectric layer 14 is 30 mm. The absorption frequency band for which wave absorption is greater than 90% (i.e., below-10 dB reflection) is estimated between 7.4 and 8.7 GHZ. Thus, varying the distance D2 between the absorber 10 and the surface to be protected 22 allows the absorber 10 to be configured to absorb a wide range of frequencies.

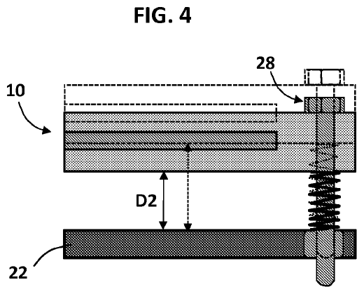

The radar absorber 10 may be mounted on the surface to be protected 22 by fixing means 28. In the example illustrated in FIG. 4, the fixing means 28 may comprise screws 28. Alternatively, the fixing means 28 may comprise a cam mechanism. In both cases, the distance D2 between the absorber 10 and the surface to be protected 22 may easily be adjusted. Of course, other equivalent fixing means 28 can be used as well. In an embodiment here the surface to be protected 22 is a vessel hull, fixing means 28 which do not require holes or openings in the hull are preferred, for example adjustable spacers affixed to the external wall of the hull.

As mentioned above, the radar absorber 10 may comprise a first dielectric layer 12 and a second dielectric layer 14, between which a water layer 16 may be enclosed.

In embodiments, the layers 12, 14 may be composed of a material with a very high resistivity. Preferably, the material has a relative permittivity εR, or dielectric constant εR, close to 3. The relative permittivity εR corresponds to the permittivity of the material forming the dielectric layers 12, 14 expressed in relation to the constant vacuum permittivity 80, which is constant. In addition, the material forming dielectric layers 12, 14 may have sufficient mechanical strength to withstand forces, such as, for example, strong winds or waves, without undergoing substantial flexure.

Preferably, the dielectric layers 12, 14 may be composed of a PolyVinyl Chloride (PVC). Alternatively, the material may be a rubber, or another material with suitable permittivity. The dielectric layers 12, 14 may be manufactured by injection molding, machining, laser cutting, water jetting or any other suitable manufacturing process.

In the illustrated example, the first and second dielectric layers 12, 14 take the form of generally flat plates extending in extension planes parallel to each other, wherein: a thickness E12 of the first layer 12, measured in the direction perpendicular to its extension plane (direction z), is about 4 mm;
a thickness E14 of the second layer 14, also measured in the direction perpendicular to its extension plane (direction z), is about 2 and mm;
a distance D1 between the first layer 12 and the second layer 14, between which the water layer 16 is located, is approximately 2 mm.
   Such dimensions optimize the absorbance performance of the radar absorber 10, and in particular affect the absorption frequencies and absorption frequency band of the radar waves 11.

In an alternative embodiment, the thickness E12 of the first dielectric layer 12 is of about 2 mm. Reducing the thickness E12 of the first dielectric layer 12 shifts the frequency band for which the radar absorber is particularly efficient towards lower frequencies. In particular, for a distance D2 between the absorber 10 and the surface to be protected 22 of about 30 mm, the 2 mm thickness E12 of the first dielectric layer 12 significantly reduces absorption of higher frequencies. The radar absorber 10 may be tuned to minimize absorption in the higher frequency band.

In some embodiments, the first and second dielectric layers 12, 14 may be configured as square plates, round plates, rectangular plates or another shaped plate. The shape of the first and second dielectric layers 12, 14 may be chosen according to the shape of the surface to be protected 22. For example, the first and second dielectric layers 12, 14 may have a length L and a width w, measured in their extension planes (plane xy), chosen according to the dimensions of the surface to be protected 22 by the radar absorber 10. In one non-limiting example, the length L may be approximately 300 mm and the width w may be approximately 300 mm. In such an example, the enclosed volume E in which water is contained may be approximately 180 000 mm³ (i.e., 0.18 L).

Furthermore, the water layer 16 enclosed between the dielectric layers 12, 14 may contain water having a temperature between 5° C. and 45° C., though in one preferred embodiment the water has a temperature of about 25° C. It is believed that the temperature of the water in the water layer 16 may influence the water layer's electrical properties, and by extension, the absorption performance of the radar absorber 10. In particular, it has been observed that 90% absorption may be obtained in a desired frequency band when the water temperature remains between 5° and 45°.

A frame 18 may be configured between the first and second dielectric layers 12, 14 and may be configured to hold water comprising the water layer 16. The frame 18 may act as a spacer to define the distance D1 between the first and the second dielectric layers 12, 14. The frame 18 may also be configured to hold a volume E of water in the water layer 16.

In an embodiment, the frame 18 may be bonded between the first and second dielectric layers 12, 14 by adhesion. Example adhesives include a PVC Gel provided by Griffon, Sikaflex 11FC Polyurethane Sealant/Adhesive provided by Sikaflex or DP420 Epoxy adhesive provided by 3M. Alternatively, the frame 18 may also be connected to the layers 12, 14 by screws, clips or another equivalent means. In some embodiments, the frame 18 may be integral with the first or the second dielectric layer 12, 14, for example by being machined or injection molded with the first or second dielectric layer 12, 14.

In addition, in this example, the frame 18 may be composed of a PVC material in order to, among other things, limit the costs associated with the manufacture of the radar absorber 10. Alternatively, the frame 18 may be composed of another material whose properties are sufficiently rigid to maintain the distance D1 between the first dielectric layer 12 and the second dielectric layer 14.

The frame 18 may be covered with a waterproof material 20 to hold water within the volume E. The waterproof material 20 may be applied on the outer periphery of the frame 18. In one embodiment, the waterproof material may be polyurethane, commercialized under the name Sikaflex®. Such a material may be used to provide high-strength, watertight joints.

In an embodiment, the frame 18 may be covered with an insulating material. The insulating material may be applied to the periphery of the frame 18. The insulating material may participate in maintaining the water temperature within the water layer 16 in the range of 5° to 45° C. The insulating material may therefore participate in the good absorption performance of the radar absorber 10.

Referring now to FIG. 2, the frame 18 may comprise an opening 26. The opening 26 allows water to be introduced into the volume E between the first and the second dielectric layers 12, 14. The opening 26 may, following the introduction of the water, be closed with a stopper (not shown). The opening 26 may further be covered with the waterproof material 20 to hold or contain the water layer 16 and prevent leakage of the water. In one embodiment, the water may be added into the frame 18 at the time the absorber 10 is manufactured. Alternatively, the water may be added to the frame 18 at the time the absorber 10 is installed in the field (i.e., when the radar absorber 10 is mounted on the surface to be protected 22). In another embodiment (not illustrated) the opening may be located at on first dielectric layer 12 or on the second dielectric layer 14.

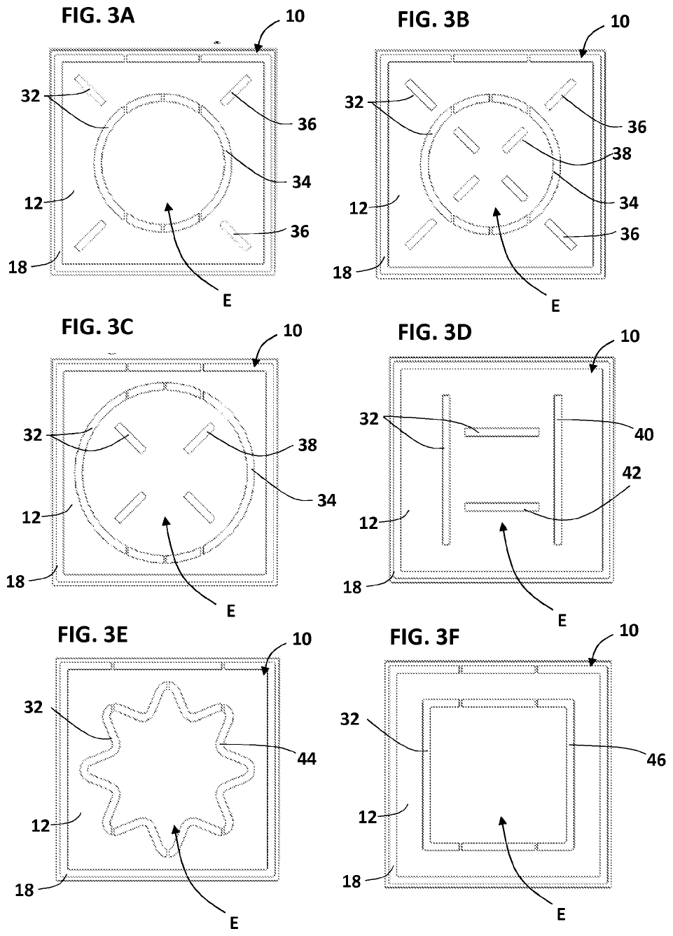

Turning to FIGS. 3A to 3F, ribs 32 may be arranged between the first and the second dielectric layers 12, 14. The ribs 32 may be located within the volume E delimited by the frame 18. The ribs 32 may separate the first dielectric layer 12 and the second dielectric layer 14 at distance D1. Further the ribs 32 contribute to the overall mechanical strength of the radar absorber 10. The distance D1 between the absorber 10 and the surface to be protected can maintained even when forces are applied to the radar absorber 10, such as, for example, strong winds or waves.

The ribs 32 may be connected to the first and second dielectric layers 12, 14 by applying an adhesive, such as: a PVC Gel provided by Griffon, Sikaflex 11FC Polyurethane Sealant/Adhesive provided by Sikaflex or DP420 Epoxy adhesive provided by 3M. Alternatively, the ribs 32 may be connected by screws, clips or another suitable structure. In some embodiments, the ribs 32 may be integral with the first or the second dielectric layers 12,14.

Further, the ribs 32 may be composed of a PVC material. Alternatively, the ribs 32 may also be composed of another suitable rigid material. In some embodiments, the ribs 32 may be formed by injection molding, machining, laser cutting or water jetting.

As illustrated, the ribs 32 may form a pattern by configuring the ribs 32 to form one or more geometric shapes, such as straight lines, circles or another form of a polygon, such as squares, hexagons, star shapes. FIG. 3A illustrates an exemplary pattern comprising a circular rib 34 and four linear ribs 36 extending diagonally across the dielectric layers 12, 14, radially outside the circular rib 34. FIG. 3B illustrates another exemplary pattern, which, in addition to the circular rib 34 and linear ribs 36 described above, may comprise four additional linear ribs 38 extending diagonally, but radially inside the circular rib 34. FIG. 3C illustrates yet another exemplary pattern, wherein the pattern may be formed by the circular rib 34 and the four linear ribs 38 extending diagonally and radially inside the circular rib 34. FIG. 3D illustrates another exemplary pattern, wherein the pattern may be formed by two long parallel ribs 40 and two short parallel ribs 42, extending perpendicularly to the long parallel ribs 40, between the two short parallel ribs 40. FIG. 3E illustrates an exemplary pattern that may be formed by ribs 32 arranged in a star shape 44, and FIG. 3F illustrates an exemplary pattern that may be formed by ribs 32 arranged in a square 46. It is believed that the exemplary patterns improve absorption and widen the absorption frequency band for which the radar absorber 10 may be particularly effective, compared to a radar absorber which does not comprise ribs 32.

Indeed, FIGS. 5A and 5B illustrate the effect of various exemplary patterns on the absorption behavior and absorption frequency bands. All of the patterns provide improved absorption and the range of frequencies where absorption occurs (i.e., absorption frequency band) is broadened when compared to an absorber with no pattern (i.e., analytical result). The improvement may be observed both for a distance D2 between the absorber 10 and the surface to be protected 22 of 0 mm (FIG. 5A), and for a distance D2 between the absorber 10 and the surface to be protected 22 of 30 mm (FIG. 5B). Although the frequency of waves 11 for which absorption is maximal shifts towards a higher frequency, a variation in the distance D2 between the absorber 10 and the surface to be protected 22 may correct the shift. Varying the distance D2 between the absorber 10 and the surface to be protected 22 may counter a slight shift in absorption frequency observed when the radar absorber 10 comprises ribs 32 forming a pattern.

The pattern formed by the ribs 32 may be symmetrical, such as those illustrated in FIGS. 3A to 3C, 3E and 3F. Alternatively, the pattern formed by the ribs 32 may be non-symmetrical, such as the pattern illustrated in FIG. 3D. The pattern may be selected depending on the absorption capabilities desired for the radar absorber 10. The symmetry of the pattern may affect the absorption of different wave propagation modes, such as the Transverse Electric (TE) mode and the Transverse Magnetic (TM).

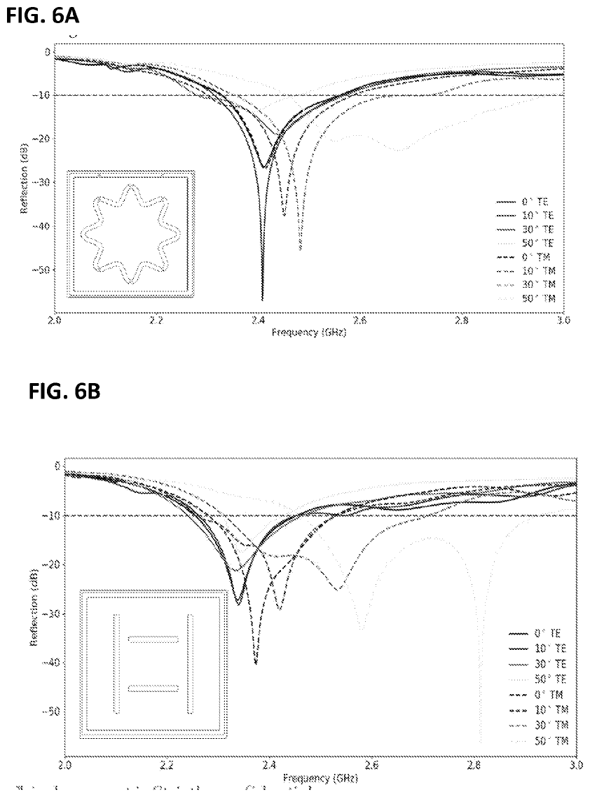

Indeed, FIG. 6A illustrates the absorption of TM and TE modes at different incidence angles for a symmetric pattern. For normal incidence, both TE and TM mode absorption responses are the same. For a given oblique incidence angle, TM absorption response slightly shifts towards higher frequencies and the absorption frequency band is broadened compared to the TE mode absorption response. However, for incidence angles of up to 50°, at least 90% absorption (i.e., less than-10 dB reflection) is achieved in the desired frequency band for both TE and TM modes. FIG. 6B illustrates the absorption of TM and TE modes at different incidence angles for a non-symmetrical pattern. For TE mode, the absorption rate is decreased as the angle of incidence increases, but 90% absorption is achieved in the desired frequency band. For TM mode, as the incidence angle increases, the absorption frequency band becomes larger and significantly shifts towards higher frequencies. Thus, the pattern may be designed to modulate the absorption responses of different propagation modes.

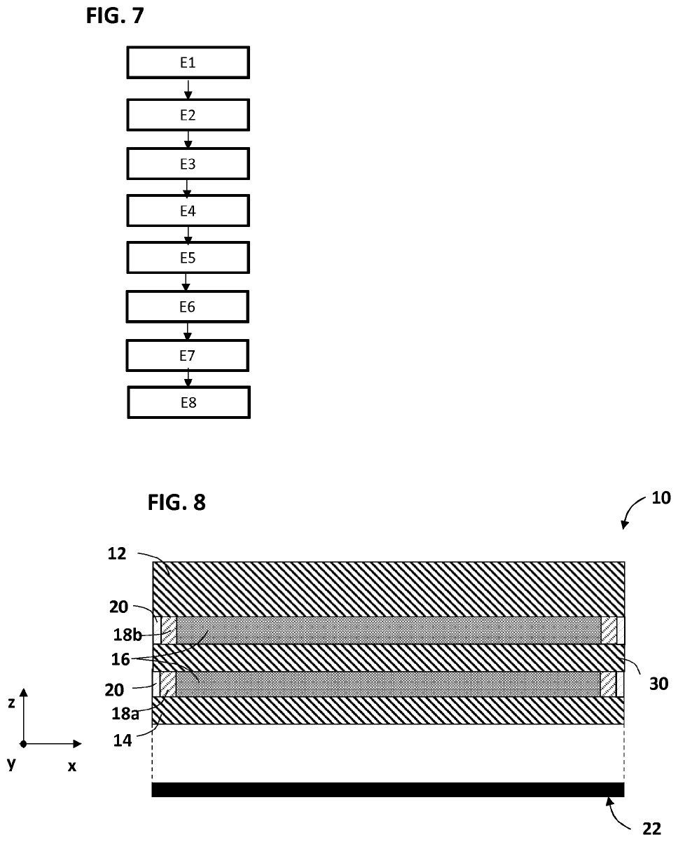

An example of an exemplary, manufacturing method for a radar absorber, such as the radar absorber 10 as described above, will now be described in more detail, with reference to FIG. 7.

As illustrated, the method may comprise a first step E1 of providing the first and the second dielectric layers 12, 14. For example, the dielectric layers 12, 14 may have a length L, a width wand desired thicknesses E12 and E14. The dielectric layers 12, 14 may be cut to size from a sheet material, for example. In some embodiments, the dielectric layers 12, 14 may be manufactured by injection molding, machining, laser cutting, water jetting or any other suitable manufacturing process.

The method may also comprise a second step E2 of fixing the frame 18 (and the ribs 32 if applicable) to the first dielectric layer 12. The fixing step may comprise a first sub-step of applying an adhesive to the first dielectric layer 12 or the frame 18 and the ribs 32, followed by a second sub-step of connecting the first dielectric layer 12 to the frame 18 and ribs 32. In embodiments where the frame 18 and/or ribs 32 are integral with the first or the second dielectric layers 12, 14, the method may be deprived of step E2 of fixing the frame 18 and/or ribs 32 to the first dielectric layer 12.

Such a method may further comprise a third step E3 of connecting the second dielectric layer 14 to the frame 18 (and, if applicable, the ribs 32). The attachment step E3 may also comprise a first sub-step of applying an adhesive, and a second sub step of connecting the second dielectric layer 14 to the frame 18 and ribs 32.

A fourth step E4 in such a method may comprise sealing the volume E defined by the frame 18 by applying the waterproof material 20 to the outside periphery of frame 18. The fourth step E4 may further comprise a sub-step of drying the waterproof material 20 applied to the periphery of the frame 18. Step E4 may also comprise a sub-step of applying an insulating material to the outside periphery of the frame 18.

The exemplary method may comprise a fifth step E5 of injecting water through the opening 26 of the frame 18. For example, water may be injected using a syringe through opening 26.

A sixth step E6 may comprise closing the opening 26 to contain or hold the water in volume E. Step E6 may comprise a first sub-step of inserting a stopper (not shown) into the opening 26 followed by a second sub-step of applying the waterproof material 20. Alternatively, step E6 may not include the first sub-step of inserting a stopper. Instead, the opening 26 may be closed by directly applying waterproof material to the opening 26.

A seventh step E7 may comprise mounting the radar absorber 10 on the surface to be protected 22. The absorber 10 may be fixed to the surface to be protected 22 by fixing means 28. The distance D2 between the surface to be protected 22 and the absorber 10 may be chosen according to the frequency band intended to be satisfactorily absorbed by the absorber 10.

In some embodiments, step E5 of injecting water through the opening 26 may be completed after step E7 of mounting the radar absorber 10 on the surface to be protected 22. In some embodiments, water may be added or removed after step E7 of mounting the radar absorber 10. Thus, it appears possible to modulate the absorption response of the radar absorber 10 whilst in use.

The invention is not limited to the above described embodiments, but is subject to variants and equivalents.

For example, as illustrated in FIG. 8, an intermediate dielectric layer 30 may be configured between the first dielectric layer 12 and the second dielectric layer 14. On either side of the intermediate layer 30, frames 18a, 18b, covered with waterproof material 20, may be configured to enclose a water layer 16. Ribs 32 may also be arranged on either side of the intermediate layer 30. By overlaying one or more intermediate dielectric layers 30, the frequency band can be modulated. In particular, it appears possible to absorb lower frequency waves, especially in the Radio Frequency (RF) wave band, in particular radio waves within a frequency band of 4-8 Ghz.

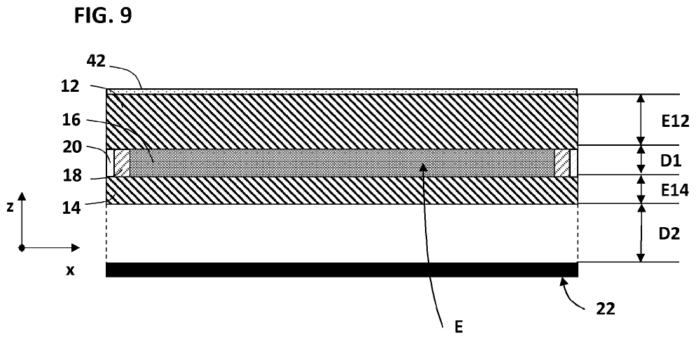

In another example, illustrated in FIG. 9, a resistive layer 42 may be configured above the first dielectric layer 12. The resistive layer 42 may have a resistance of around 300 ohms. The resistive layer 42 may for example be an Indium tin oxide (ITO) film applied to the first dielectric layer 12. The resistive layer 42 may provide additional absorption in the low frequencies. In particular, the resistive layer 42 may provide absorption in the 400 MHz to 1 Ghz frequency band.

Further, the dielectric layers 12, 14 may be curved or be configured in a cylindrical shape. In embodiments, the shape of the exemplary dielectric layers may be configured to take the shape of, or cover, the surface to be protected. For example, if the radius of the curvature of a cylindrical surface is sufficiently above the wavelength of the wave to be absorbed, and in particular if the radius is at least ten times larger than the wavelength, exemplary radar absorbers can have the same thicknesses and distances as those described above. For other curvatures or cylinders, the thickness E12, E14 of the dielectric layers 12, 14 may be adapted to optimize the performance of the absorber 10.

1-25. (canceled)

26. A radar absorber comprising at least:
a first dielectric layer configured to face away from a surface to be protected;
a second dielectric layer configured to face towards the surface to be protected; and
a frame configured to hold water in a water layer enclosed in a volume between the first and the second dielectric layers.

27. The radar absorber according to claim 26, further comprising fixing means configured to mount the radar absorber to the surface to be protected, wherein the fixing means are configured to define a gap between the second dielectric layer and the surface to be protected.

28. The radar absorber according to claim 27, wherein the fixing means are configured to set a distance separating the surface to be protected from the second dielectric layer, wherein the distance is comprised in an interval between 0 mm and 50 mm.

29. The radar absorber according to claim 27, wherein the fixing means comprise screws.

30. The radar absorber according to claim 26, wherein the frame delimits the volume between the first and the second dielectric layers.

31. The radar absorber according to claim 30, wherein an outer periphery of the frame is covered with a waterproof material.

32. The radar absorber according to claim 26, further comprising ribs arranged between the first and the second dielectric layer.

33. The radar absorber according to claim 32, wherein the ribs form a pattern and the pattern comprises one or more geometric shapes.

34. The radar absorber according to claim 33, wherein the pattern is symmetrical or the pattern is not symmetrical.

35. The radar absorber according to claim 26, wherein the first and second dielectric layers are composed of a PolyVinyl Chloride (PVC) or a rubber.

36. The radar absorber according to claim 26, wherein the water layer has a temperature comprised between 5° C. and 45° C.

37. The radar absorber according to claim 26, wherein the first and the second dielectric layers take the form of continuous plates, of constant thickness and generally planar.

38. The radar absorber according to claim 37, wherein:
the first dielectric layer has a thickness of about 4 mm or a thickness of about 2 mm;
the second dielectric layer has a thickness of about 2 mm; and
a distance between the first dielectric layer and the second dielectric layer is about 2 mm.

39. The radar absorber according to claim 26, further comprising at least one intermediate dielectric layer configured between the first dielectric layer and the second dielectric layer, and the water layer being configured on either side of each intermediate layer.

40. The radar absorber according to claim 26, further comprising a resistive layer placed on an outer surface of the first dielectric layer.

41. A method for manufacturing a water absorber comprising:
providing at least a first dielectric layer and a second dielectric layer; and
configuring a frame configured to hold water and form a water layer between the first dielectric layer and the second dielectric layer.

42. The method according to claim 41, further comprising mounting the radar absorber to a surface to be protected at a distance separating the surface to be protected from the radar absorber comprised in an interval between 0 mm and 50 mm.

43. The method according to claim 41, further comprising:
connecting the frame and the first dielectric layer; and
connecting the second dielectric layer and the frame to define a volume between the first and second dielectric layer.

44. The method according to claim 43, further comprising:
injecting water through an opening of the frame to fill the volume; and
applying a waterproof material on an outer periphery of the frame.

45. The method according to claim 41, further comprising providing ribs to the first dielectric layer or the second dielectric layer.

46. The method according to claim 45, further comprising providing the ribs to form a pattern comprising one or more geometric shapes.

47. The method according to claim 41, further comprising mounting one or more intermediate dielectric layers between the first dielectric layer and the second dielectric layer, each intermediate layer being arranged between two water layers.

48. The method according to claim 41, further comprising providing a resistive layer on the first dielectric layer.
